(19) United States
(12) Patent Application Publication
(10) Pub. No.: US 2026/0275500 A1
(43) Pub. Date: Sep. 17, 2026

(54) SUBSTRATE SUPPORTING STAGE FOR DEPOSITION, AND DEPOSITION DEVICE INCLUDING THE SAME

(71) Applicant: Samsung Display Co., Ltd., Yongin-Si (KR)

(72) Inventor: Jeong Won HAN, Yongin-si (KR)

(21) Appl. No.: 19/178,866

(22) Filed: Apr. 15, 2025

(30) Foreign Application Priority Data
Jul. 26, 2024 (KR) 10-2024-0099556

(51) Int. Cl. C23C 14/50; C23C 14/04; H10P 72/76

(52) U.S. Cl. CPC C23C 14/50; C23C 14/042; H10P 72/7606

(57) ABSTRACT

A substrate supporting stage for deposition according to an embodiment includes: a base portion; an edge chucking portion located on a lateral surface of a side wall of the base portion; and a heater located on the edge chucking portion. The edge chucking portion includes a main portion, a first protruding portion, and a second protruding portion, the first protruding portion and the second protruding portion extending downward from the main portion in a height direction, and the first protruding portion has a cross-section narrowed in accordance with a distance from the main portion in the height direction.

### CROSS-REFERENCE TO RELATED APPLICATION

This application claims priority to and the benefit of Korean Patent Application No. 10-2024-0099556 filed in the Korean Intellectual Property Office on Jul. 26, 2024, the entire contents of which are incorporated herein by reference.

### BACKGROUND

### 1. Field

The present disclosure relates to a substrate supporting stage for deposition, and a deposition device including the same.

### 2. Description of the Related Art

Display devices include a liquid crystal display (LCD), a plasma display panel (PDP), an organic light emitting diode (OLED) device, a field emission display (FED), and an electrophoretic display device.

Organic light emitting display devices have garnered much attention as next-generation display devices because of their merits such as wide viewing angle, fast response rate, and low power consumption, as well as light weight and slim size.

The organic light emitting display device may include a first electrode and a second electrode opposite each other, and a light emitting layer located between the first electrode and the second electrode. The first electrode, the second electrode, and the light emitting layer may be formed on a substrate by a deposition method using a fine metal mask (FMM).

During the deposition process, it is necessary to minimize a shadow effect by stably fixing the substrate and reducing a gap between the mask and the substrate.

### SUMMARY

The present disclosure provides a substrate supporting stage for deposition for stably fixing the substrate and reducing a gap between a mask and a substrate, and a deposition device including the same.

However, features of the present disclosure may not be limited to the above-described features, and may be extended in various ways within a range of technical scopes included in the present disclosure.

An embodiment of the present disclosure provides a substrate supporting stage for deposition including: a base portion; an edge chucking portion located on a lateral surface of a side wall of the base portion; and a heater located on the edge chucking portion. The edge chucking portion includes a main portion, a first protruding portion, and a second protruding portion, the first protruding portion and the second protruding portion extending downward from the main portion in a height direction, and the first protruding portion has a cross-section narrowed in accordance with a distance from the main portion in the height direction.

An embodiment of the present disclosure provides a deposition device including: a chamber for providing a process region; a deposition member located in the chamber and providing a process material; a substrate supporting stage opposite the deposition member in a height direction and supporting a substrate; and a mask assembly located between the substrate supporting stage and the deposition member. The substrate supporting stage includes an edge chucking portion located on a lateral surface of a side wall of the base portion, and a heater located on the edge chucking portion. The edge chucking portion includes a main portion, a first protruding portion, and a second protruding portion, the first protruding portion and the second protruding portion extending downward from the main portion in a height direction, and the first protruding portion has a cross-section narrowed in accordance with a distance from the main portion in the height direction.

The second protruding portion may be located between the side wall and the first protruding portion in a planar direction that is perpendicular to the height direction, and a cross-section of the second protruding portion may be substantially constant in the height direction.

A first thickness of the first protruding portion may not be equal to a second thickness of the second protruding portion.

The first thickness may be greater than the second thickness.

The second protruding portion may not protrude downward further than the side wall in the height direction.

The first protruding portion may protrude downward further than the side wall in the height direction.

The edge chucking portion may include a shape memory material.

The main portion, the first protruding portion, and the second protruding portion may include the shape memory material.

The main portion and the second protruding portion may include the shape memory material, and the first protruding portion may include a ball inserted into the main portion.

The substrate supporting stage for deposition may further include a center chucking portion located below the base portion in the height direction and located on a lateral surface of the edge chucking portion in a planar direction that is perpendicular to the height direction.

According to the embodiments, the substrate supporting stage for deposition for stably fixing the substrate and reducing the gap between the mask and the substrate, and the deposition device including the same may be provided.

The effects of the present embodiments are not limited to the above-described effects, and may be expanded in various ways without departing from the spirit and scope of the present disclosure.

### BRIEF DESCRIPTION OF THE DRAWINGS

FIG. 1 shows a cross-sectional view of a deposition device according to an embodiment.

FIG. 2 shows a cross-sectional view of a substrate supporting stage according to an embodiment.

FIGS. 3, 4, 5, 6, 7, 8, and 9 show cross-sectional views on operations of a substrate supporting stage according to an embodiment.

FIGS. 10, 11, and 12 show cross-sectional views on a portion of a substrate supporting stage according to embodiments.

FIGS. 13, 14, 15, and 16 show top plan views on a portion of a substrate supporting stage according to embodiments.

FIG. 17 shows a cross-sectional view on a substrate supporting stage according to an embodiment.

FIG. 18 shows a cross-sectional view on a substrate supporting stage according to an embodiment.

FIG. 19 shows a cross-sectional view on a substrate supporting stage according to an embodiment.

### DETAILED DESCRIPTION

The embodiments will be described more fully hereinafter with reference to the accompanying drawings, in which embodiments are shown. As those skilled in the art would realize, the described embodiments may be modified in various different ways, all without departing from the spirit or scope of this disclosure.

Parts that are irrelevant to the description will be omitted to clearly describe this disclosure, and the same elements will be designated by the same reference numerals throughout the specification.

The accompanying drawings are provided only in order to allow embodiments disclosed in the present specification to be easily understood and are not to be interpreted as limiting the spirit disclosed in the present specification, and it is to be understood that this disclosure includes all modifications, equivalents, and substitutions without departing from the scope and spirit of this disclosure.

The size and thickness of each configuration shown in the drawings are arbitrarily shown for better understanding and ease of description, but the present disclosure is not limited thereto. In the drawings, the thicknesses of layers, films, panels, regions, etc., are enlarged for clarity. The thicknesses of some layers and areas are exaggerated for convenience of explanation.

It should be understood that when an element such as a layer, film, region, or substrate is referred to as being “on” another element, it may be directly on the other element or intervening elements may also be present. In contrast, when an element is referred to as being “directly on” another element, there are no intervening elements present. The word “on” or “above” means positioned on or below the object portion, and does not necessarily mean positioned on the upper side of the object portion based on a gravitational direction.

Unless explicitly stated to the contrary, the word “comprise,” and variations such as “comprises” and “comprising,” should be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

When it is stated that a part is "connected” to another part, the part may be “directly connected” to the other part, may be “connected” to the other part through a third part, or may be connected to the other part physically or electrically, and they may be referred to by different titles depending on positions or functions, but respective parts that are substantially integrated into one body may be connected to each other.

Various embodiments and variations will now be described with reference to accompanying drawings.

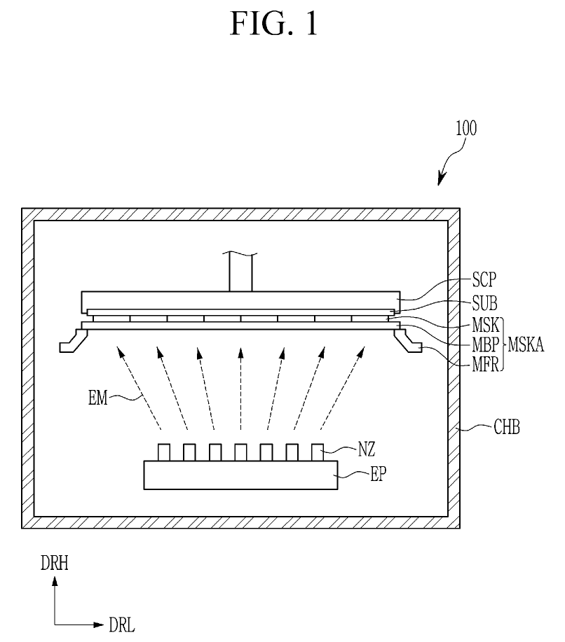

A deposition device 100 according to an embodiment will now be described with reference to FIG. 1. FIG. 1 shows a cross-sectional view of the deposition device 100 according to an embodiment.

Referring to FIG. 1, the deposition device 100 may include a chamber CHB, a deposition member EP, a mask assembly MSKA, and a substrate supporting stage SCP.

The chamber CHB may provide an internal process region for performing a deposition process on a substrate SUB. The internal space of the chamber CHB may be a sealed space, and a deposition condition of the deposition device 100 may be set as vacuum.

The deposition member EP, the substrate supporting stage SCP, and the mask assembly MSKA may be located in the internal space of the chamber CHB.

The substrate supporting stage SCP may be opposite the deposition member EP in a height direction DRH in the internal space of the chamber CHB.

The substrate supporting stage SCP may support and transfer the substrate SUB on which processes will be performed. The substrate supporting stage SCP may fix the substrate SUB on which a deposition material is deposited on the mask assembly MSKA.

The mask assembly MSKA may include a mask MSK, a mask frame MFR, and a mask support bar MBP.

The mask frame MFR and the mask support bar MBP may support the mask MSK, and the mask support bar MBP may be attached to the mask frame MFR.

The deposition member EP may include a space in which a deposition material EM is received and at least one nozzle NZ. The deposition material EM may include an inorganic material that may be sublimated or gasified, a metal, or an organic material. For example, the deposition material EM may include an organic material for forming layers included in a display panel.

The deposition material EM may be sublimated or gasified and may be sprayed toward the substrate SUB through the nozzle NZ.

The deposition material EM may pass through the mask assembly MSKA and may be deposited on the substrate SUB.

The deposition device 100 according to an embodiment is shown to perform a deposition process on the substrate SUB opposite the deposition member EP in the height direction DRH in a cross-sectional view, the embodiment is not limited thereto, and while the substrate SUB may be opposite the deposition member EP in a horizontal direction DRL perpendicular to the height direction DRH, the deposition process may be performed. The deposition material EM may pass through the mask assembly MSKA and may be deposited on the substrate SUB.

Although not shown, the deposition device 100 may further include a mechanical device for realizing an inline system.

The deposition device 100 may further include a mask assembly support portion for preventing the mask assembly MSKA having a large surface area from drooping due to gravity. The mask assembly support portion may be fixed to at least one of the side walls of the chamber CHB, and may support the mask assembly MSKA.

In an embodiment, the deposition device 100 may further include a heat dissipating member located between the mask assembly MSKA and the deposition member EP. The heat dissipating member may include a material with high thermal conductivity. For example, the heat dissipating member may include a metal such as aluminum or copper, alloys thereof, carbon, or graphite. The heat dissipating member may absorb heat discharged by the deposition member EP to prevent the mask assembly MSKA from being transformed by heat during the deposition process.

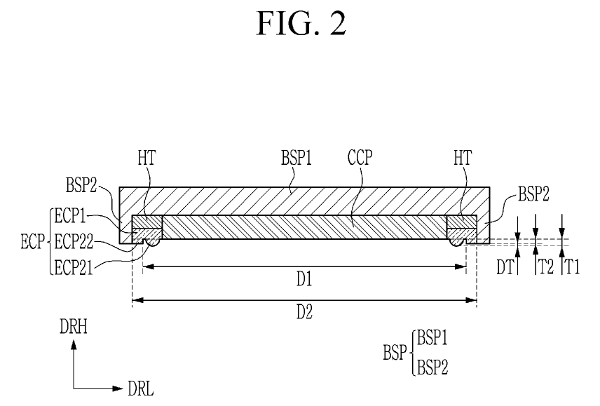

The substrate supporting stage SCP according to an embodiment will now be described with reference to FIG. 2. FIG. 2 shows a cross-sectional view of a substrate supporting stage according to an embodiment.

Referring to FIG. 2, the substrate supporting stage SCP may include a base portion BSP, a center chucking portion CCP, an edge chucking portion ECP, and a heater HT.

The base portion BSP may include a planar portion BSP1 opposite the substrate SUB and a side wall portion BSP2 located on an edge of the planar portion BSP1.

The center chucking portion CCP, the edge chucking portion ECP, and the heater HT may be attached to the base portion BSP.

The center chucking portion CCP may be attached to the planar portion BSP1 of the base portion BSP.

The center chucking portion CCP may be an electrostatic chuck or an adhesive chuck. The center chucking portion CCP may support the substrate SUB by adsorbing a central portion of the substrate SUB using a static electricity force or an adhesive force.

The edge chucking portion ECP may be located near the side wall portion BSP2 of the base portion BSP in the horizontal direction DRL, and the edge chucking portion ECP may be located on a lateral surface of the center chucking portion CCP. The edge chucking portion ECP may be located between the side wall portion BSP2 of the base portion BSP and the center chucking portion CCP in the horizontal direction DRL.

The heater HT may be located on the edge chucking portion ECP in the height direction DRH.

The edge chucking portion ECP may include a shape memory material such as a shape memory polymer or a shape memory alloy.

As the temperature works as an external force, the edge chucking portion ECP may be transformed and restored depending on the temperature.

The edge chucking portion ECP may include a main portion ECP1, and a first protruding portion ECP21 and a second protruding portion ECP22 extending downward from the main portion ECP1.

The main portion ECP1 of the edge chucking portion ECP may be disposed on a lateral surface of the center chucking portion CCP. The heater HT may be located on the main portion ECP1.

A cross-section of the first protruding portion ECP21 of the edge chucking portion ECP may become smaller in accordance with a distance from the main portion ECP1 of the edge chucking portion ECP.

The cross-section of the second protruding portion ECP22 of the edge chucking portion ECP may be substantially constant in the height direction DRH.

The heater HT may be located on the main portion ECP1 of the edge chucking portion ECP, and the edge chucking portion ECP may receive heat energy from the heater HT and its shape may be transformed. When supplying of heat energy from the heater HT is interrupted, the shape of the edge chucking portion ECP may be restored.

A first thickness T1 of the first protruding portion ECP21 of the edge chucking portion ECP may be greater than a second thickness T2 of the second protruding portion ECP22 of the edge chucking portion ECP. The first protruding portion ECP21 of the edge chucking portion ECP may be thicker than the second protruding portion ECP22 of the edge chucking portion ECP by a thickness difference DT, and the first protruding portion ECP21 may protrude further than the second protruding portion ECP22 by the thickness difference DT.

The second protruding portion ECP22 of the edge chucking portion ECP may not protrude further than the side wall portion BSP2 of the base portion BSP in the height direction DRH. The first protruding portion ECP21 of the edge chucking portion ECP may protrude further than the side wall portion BSP2 of the base portion BSP downward in the height direction DRH.

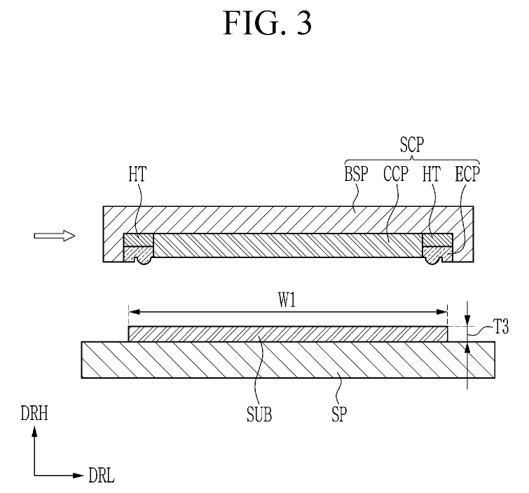

The second thickness T2 of the second protruding portion ECP22 of the edge chucking portion ECP may be less than a third thickness T3, e.g., see FIG. 3, of the substrate SUB mounted on the substrate supporting stage SCP.

A first gap D1 between the second protruding portions ECP22 of the edge chucking portion ECP opposite each other in the horizontal direction DRL may be less than a width W1, e.g., see FIG. 3, of the substrate SUB mounted on the substrate supporting stage SCP, and a second gap D2 between the side wall portions BSP2 of the base portion BSP opposite each other in the horizontal direction DRL may be greater than the width W1 of the substrate SUB mounted on the substrate supporting stage SCP.

Heat energy may be supplied to the first protruding portion ECP21 and the second protruding portion ECP22 of the edge chucking portion ECP from the heater HT, and pressure is applied to the substrate supporting stage SCP from an outside, the first protruding portion ECP21 and the second protruding portion ECP22 of the edge chucking portion ECP may be transformed, and the substrate SUB may be sandwiched and held between the edge chucking portion ECP.

The first protruding portion ECP21 of the edge chucking portion ECP may be thicker than the second protruding portion ECP22 of the edge chucking portion ECP by the thickness difference DT and may protrude further than the base portion BSP of the substrate supporting stage SCP.

When the supply of heat energy to the first protruding portion ECP21 and the second protruding portion ECP22 of the edge chucking portion ECP is interrupted, the shape of the first protruding portion ECP21 may be restored, the substrate SUB may be spaced away from the center chucking portion CCP, and the substrate SUB may be detached from the substrate supporting stage SCP.

The cross-section of the first protruding portion ECP21 of the restored edge chucking portion ECP may be narrowed in accordance with a distance to the substrate, and the edge chucking portion ECP may be easily detached from the substrate SUB.

An operation of the substrate supporting stage SCP will now be described in detail with reference to FIGS. 3 to 9 together with FIGS. 1 and 2. FIGS. 3 to 9 show cross-sectional views on operations of a substrate supporting stage SCP according to an embodiment.

Referring to FIG. 3, the substrate supporting stage SCP may be moved over the substrate SUB on a supporting plate SP.

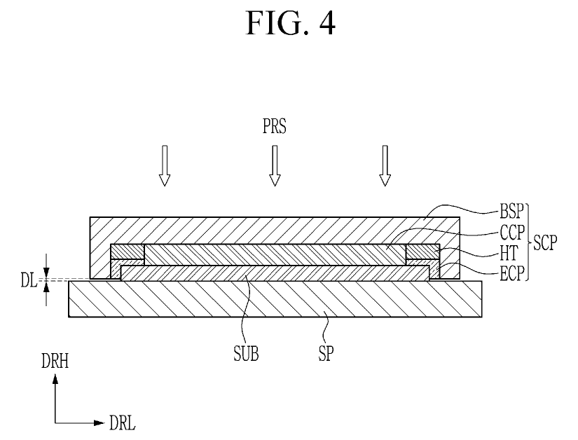

Referring to FIG. 4, a pressure PRS may be applied so that the substrate supporting stage SCP may be closely attached to the substrate SUB, and heat energy may be applied to the edge chucking portion ECP through the heater HT.

When heat energy is supplied to the first protruding portion ECP21 and the second protruding portion ECP22 of the edge chucking portion ECP from the heater HT and pressure is applied to the substrate supporting stage SCP from the outside, the first protruding portion ECP21 and the second protruding portion ECP22 of the edge chucking portion ECP are transformed, and the substrate SUB may be sandwiched and held between the edge chucking portion ECP.

The substrate SUB may be sandwiched and held between the edge chucking portion ECP, the substrate SUB may be closely attached to the center chucking portion CCP that is an electrostatic chuck or an adhesive chuck, the center chucking portion CCP may chuck the substrate SUB, and the substrate SUB may be supported by the center chucking portion CCP and the edge chucking portion ECP. The substrate SUB may be supported by the center chucking portion CCP, and an edge portion of the substrate SUB may be additionally supported and fixed by the edge chucking portion ECP so that the substrate supporting stage SCP may stably support the substrate SUB.

As described above, the first gap D1 between the second protruding portions ECP22 of the edge chucking portion ECP opposite each other in the horizontal direction DRL may be less than the width W1 of the substrate SUB mounted on the substrate supporting stage SCP, and the second gap D2 between the side wall portions BSP2 of the base portion BSP opposite each other in the horizontal direction DRL may be greater than the width W1 of the substrate SUB mounted on the substrate supporting stage SCP. Therefore, as the edge chucking portion ECP is transformed, the substrate SUB may be sandwiched and held between the edge chucking portion ECP.

The second thickness T2 of the second protruding portion ECP22 of the edge chucking portion ECP may be substantially equal to or less than the third thickness T3 of the substrate SUB mounted on the substrate supporting stage SCP. Therefore, when the substrate supporting stage SCP is mounted, the surface of the substrate SUB may protrude further than the edge chucking portion ECP of the substrate supporting stage SCP. When the substrate supporting stage SCP is mounted, the surface of the substrate SUB may protrude further than the base portion BSP of the substrate supporting stage SCP by a predetermined gap DL.

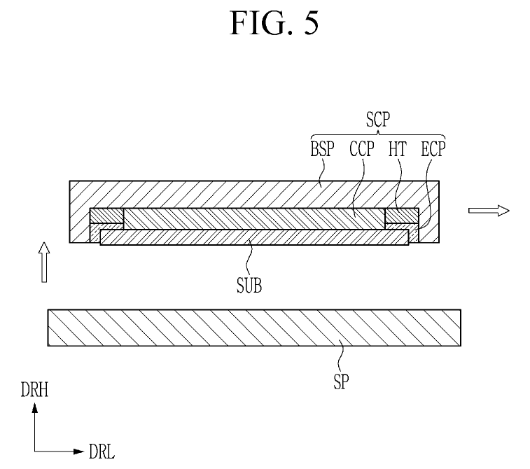

Referring to FIG. 5, the substrate supporting stage SCP on which the substrate SUB is mounted may be spaced away from the supporting plate SP, and may be moved into the chamber CHB of the deposition device 100 of FIG. 1.

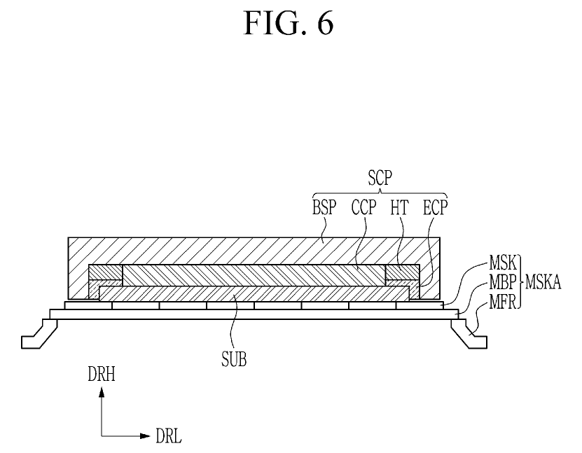

Referring to FIG. 6, the substrate SUB may be fixed on the mask MSK of the mask assembly MSKA.

When mounted on the substrate supporting stage SCP, the surface of the substrate SUB may protrude further than the base portion BSP of the substrate supporting stage SCP so that the surface of the substrate SUB may be closely attached to the mask MSK of the mask assembly MSKA to avoid unnecessary gaps. When at least a portion of the substrate supporting stage SCP protrudes further than the surface of the substrate SUB, an unnecessary gap may be generated between the substrate SUB and the mask MSK by a protruding portion of the substrate supporting stage SCP. However, according to the embodiment, the surface of the substrate SUB may be closely attached to the mask MSK of the mask assembly MSKA to avoid the unnecessary gap.

The substrate SUB may be fixed on the mask MSK of the mask assembly MSKA in the chamber CHB, and the deposition process may be performed.

As described, the surface of the substrate SUB is closely attached to the mask MSK of the mask assembly MSKA to avoid unnecessary gaps during the deposition process, thereby reducing the generation of shadow effect and increasing accuracy of the deposition process.

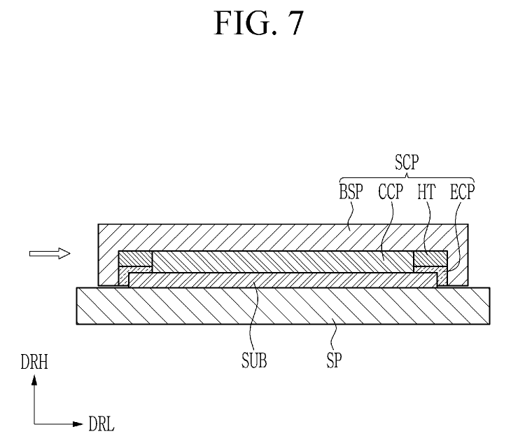

Referring to FIG. 7, the substrate supporting stage SCP supporting the substrate SUB of which the deposition process is completed may be moved onto the supporting plate SP together with the substrate SUB.

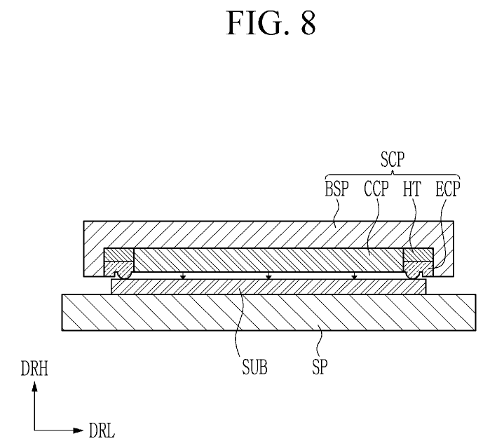

Referring to FIG. 8, when the supply of heat energy to the first protruding portion ECP21 and the second protruding portion ECP22 of the edge chucking portion ECP is interrupted, the shape of the first protruding portion ECP21 may be restored.

As described above, the first thickness T1 of the first protruding portion ECP21 of the edge chucking portion ECP may be greater than the second thickness T2 of the second protruding portion ECP22 of the edge chucking portion ECP. The first protruding portion ECP21 of the edge chucking portion ECP may be thicker than the second protruding portion ECP22 of the edge chucking portion ECP by the thickness difference DT, and may protrude further by the thickness difference DT.

The second protruding portion ECP22 of the edge chucking portion ECP may not protrude further than the base portion BSP in the height direction DRH. The first protruding portion ECP21 of the edge chucking portion ECP may protrude further than the base portion BSP in the height direction DRH.

The first protruding portion ECP21 of the edge chucking portion ECP may be thicker than the second protruding portion ECP22 of the edge chucking portion ECP by the thickness difference DT, and may protrude further than the base portion BSP of the substrate supporting stage SCP.

Hence, when the shapes of the first protruding portion ECP21 and the second protruding portion ECP22 of the edge chucking portion ECP are restored, the shape of the first protruding portion ECP21 is restored so that the first protruding portion ECP21 may push the substrate SUB downward, and the substrate SUB may be spaced away from the center chucking portion CCP, and the substrate SUB may be detached from the substrate supporting stage SCP. When the shape of the edge chucking portion ECP is restored to push out the substrate SUB, the center chucking portion CCP may release the substrate SUB.

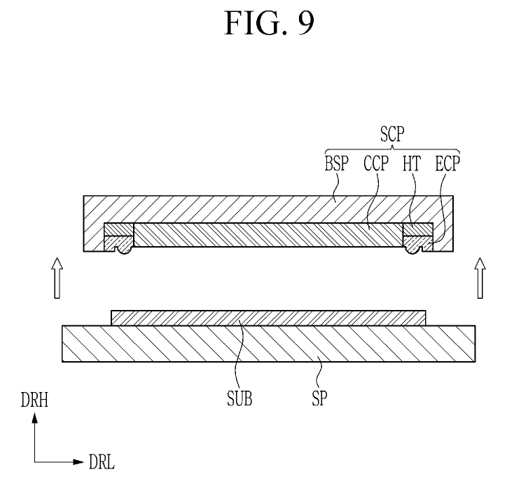

Referring to FIG. 9, the substrate supporting stage SCP from which the substrate SUB is detached may be spaced away from the supporting plate SP, and the processed substrate SUB may be stored in the supporting plate SP.

According to the embodiment, the substrate SUB may be sandwiched and held between the edge chucking portions ECP, and the substrate SUB may be closely attached to the center chucking portion CCP that is an electrostatic chuck or an adhesive chuck and may be supported by the center chucking portion CCP. Therefore, the substrate SUB is supported by the center chucking portion CCP, and the edge portion of the substrate SUB is additionally supported and fixed by the edge chucking portion ECP so that the substrate supporting stage SCP may stably support the substrate SUB.

When mounted on the substrate supporting stage SCP, the surface of the substrate SUB may protrude further than the base portion BSP of the substrate supporting stage SCP and may be closely attached to the mask MSK of the mask assembly MSKA to avoid unnecessary gaps. Therefore, generation of the shadow effect may be reduced during the deposition process, and the accuracy of the deposition process may be increased.

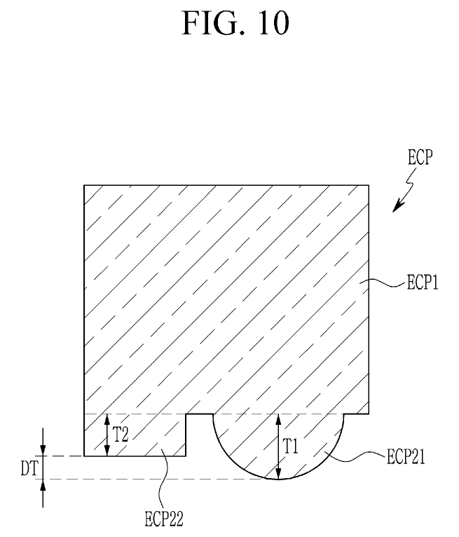

A shape of the edge chucking portion ECP of the substrate supporting stage SCP will now be described with reference to FIGS. 10 to 12. FIGS. 10 to 12 show cross-sectional views on a portion of a substrate supporting stage according to embodiments.

Referring to FIG. 10, the main portion ECP1 of the edge chucking portion ECP of the substrate supporting stage SCP according to an embodiment may have a substantially quadrangular cross-sectional shape, and the first protruding portion ECP21 may have a semicircular cross-sectional shape of which the cross-section is narrowed in accordance with a distance from the main portion ECP1, and the second protruding portion ECP22 may have a substantially quadrangular cross-sectional shape.

As described above, the first protruding portion ECP21 of the edge chucking portion ECP may have the first thickness T1, the second protruding portion ECP22 may have the second thickness T2, and the first thickness T1 may be greater than the second thickness T2. The first protruding portion ECP21 of the edge chucking portion ECP may be thicker than the second protruding portion ECP22 of the edge chucking portion ECP by the thickness difference DT.

When the shape of the edge chucking portion ECP is changed to support the substrate SUB, and the shape of the edge chucking portion ECP is restored to detach the substrate SUB, the first protruding portion ECP21 of the restored edge chucking portion ECP may protrude toward the substrate SUB further than the second protruding portion ECP22, and the cross-section of the first protruding portion ECP21 may be narrowed in accordance with a distance to the substrate so that the substrate SUB may be easily detached from the edge chucking portion ECP.

Many characteristics of the above-described embodiments may be applicable to the edge chucking portion according to the present embodiment.

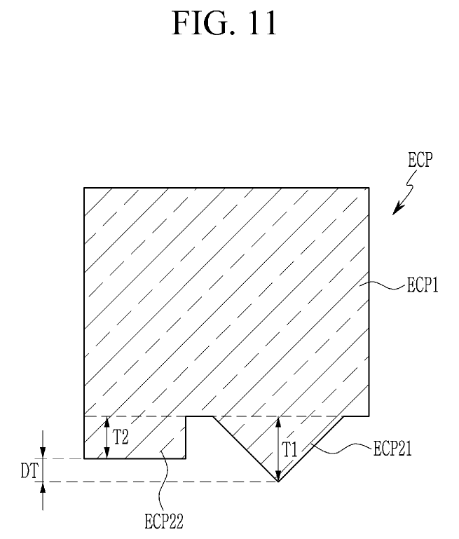

Referring to FIG. 11, the main portion ECP1 of the edge chucking portion ECP of the substrate supporting stage SCP according to an embodiment may have a substantially quadrangular cross-sectional shape, the first protruding portion ECP21 may have an inverted-triangular cross-sectional shape of which the cross-section is narrowed in accordance with a distance from the main portion ECP1, and the second protruding portion ECP22 may have a substantially quadrangular cross-sectional shape.

As described above, the first protruding portion ECP21 of the edge chucking portion ECP may have the first thickness T1, the second protruding portion ECP22 may have the second thickness T2, and the first thickness T1 may be greater than the second thickness T2. The first protruding portion ECP21 of the edge chucking portion ECP may be thicker than the second protruding portion ECP22 of the edge chucking portion ECP by the thickness difference DT.

When the shape of the edge chucking portion ECP is changed to support the substrate SUB, and the shape of the edge chucking portion ECP is restored to detach the substrate SUB, the first protruding portion ECP21 of the restored edge chucking portion ECP may protrude toward the substrate SUB further than the second protruding portion ECP22, and the cross-section of the first protruding portion ECP21 may be narrowed in accordance with a distance to the substrate so that the substrate SUB may be easily detached from the edge chucking portion ECP.

Many characteristics of the above-described embodiments may be applicable to the edge chucking portion according to the present embodiment.

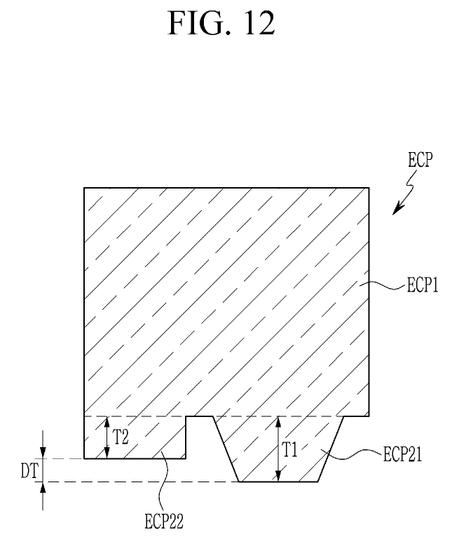

Referring to FIG. 12, the main portion ECP1 of the edge chucking portion ECP of the substrate supporting stage SCP according to an embodiment may have a substantially quadrangular cross-sectional shape, the first protruding portion ECP21 may have a trapezoidal cross-sectional shape of which the cross-section is narrowed in accordance with a distance from the main portion ECP1, and the second protruding portion ECP22 may have a substantially quadrangular cross-sectional shape.

As described above, the first protruding portion ECP21 of the edge chucking portion ECP may have the first thickness T1, the second protruding portion ECP22 may have the second thickness T2, and the first thickness T1 may be greater than the second thickness T2. The first protruding portion ECP21 of the edge chucking portion ECP may be thicker than the second protruding portion ECP22 of the edge chucking portion ECP by the thickness difference DT.

When the shape of the edge chucking portion ECP is changed to support the substrate SUB, and the shape of the edge chucking portion ECP is restored to detach the substrate SUB, the first protruding portion ECP21 of the restored edge chucking portion ECP protrudes toward the substrate SUB further than the second protruding portion ECP22, and the cross-section of the first protruding portion ECP21 may be narrowed in accordance with a distance to the substrate so that the substrate SUB may be easily detached from the edge chucking portion ECP.

Many characteristics of the above-described embodiments may be applicable to the edge chucking portion according to the present embodiment.

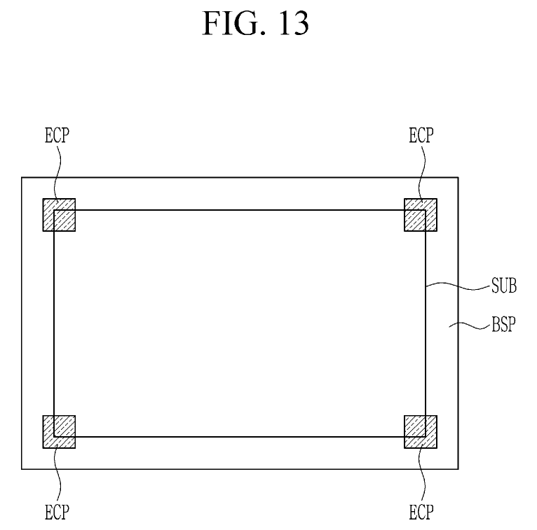

A position of the edge chucking portion ECP of the substrate supporting stage SCP in a plan view will now be described with reference to FIGS. 13 to 16. FIGS. 13 to 16 show top plan views on a portion of a substrate supporting stage according to embodiments.

Referring to FIG. 13, the base portion BSP of the substrate supporting stage SCP according to an embodiment may have a substantially quadrangular planar shape, and similar to this, the substrate SUB supported by the substrate supporting stage SCP may have a substantially quadrangular planar shape.

The edge chucking portion ECP of the substrate supporting stage SCP may be disposed at locations corresponding to four edges, e.g., corners, of the substrate SUB.

The edge chucking portion ECP of the substrate supporting stage SCP may support the four edges of the substrate SUB.

Many characteristics of the above-described embodiments may be applicable to the edge chucking portion according to the present embodiment.

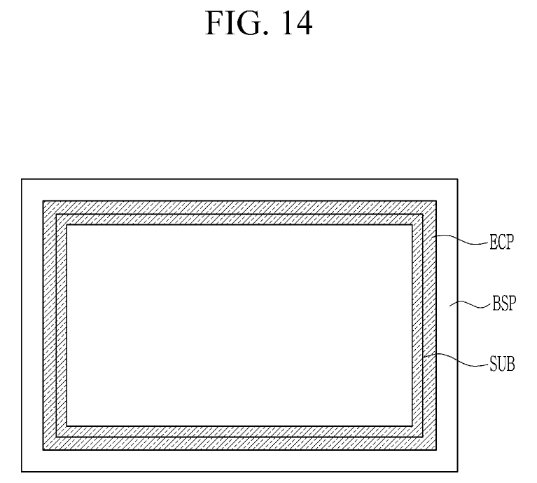

Referring to FIG. 14, the base portion BSP of the substrate supporting stage SCP according to an embodiment may have a substantially quadrangular planar shape, and similar to this, the substrate SUB supported by the substrate supporting stage SCP may have a substantially quadrangular planar shape.

The edge chucking portion ECP of the substrate supporting stage SCP may have a planar shape in the form of a square ring located along circumference of the substrate SUB.

The edge chucking portion ECP of the substrate supporting stage SCP may support the four edges of the substrate SUB.

Many characteristics of the above-described embodiments may be applicable to the edge chucking portion according to the present embodiment.

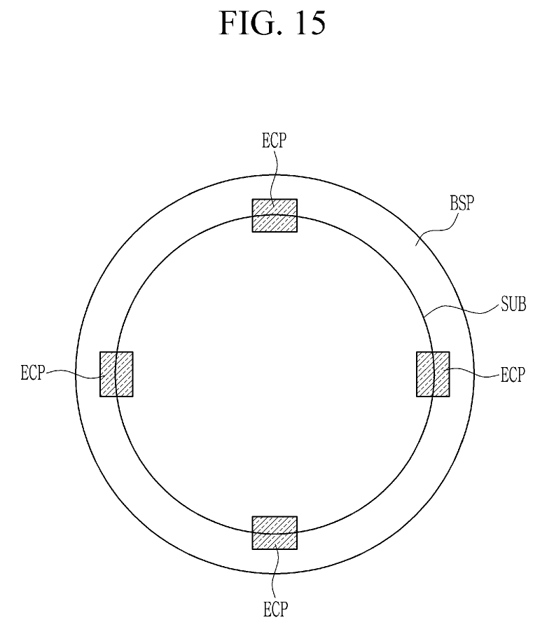

Referring to FIG. 15, the base portion BSP of the substrate supporting stage SCP according to an embodiment may have a substantially circular planar shape, and similar to this, the substrate SUB supported by the substrate supporting stage SCP may have a substantially circular planar shape.

The edge chucking portion ECP of the substrate supporting stage SCP may be arranged at regular gaps along the circumference of the substrate SUB. According to the shown embodiment, there are four edge chucking portions ECP, and the embodiment is not limited thereto, and there may be at least two edge chucking portions ECP.

The edge chucking portion ECP of the substrate supporting stage SCP may support at least two portions of the edge of the substrate SUB.

Many characteristics of the above-described embodiments may be applicable to the edge chucking portion according to the present embodiment.

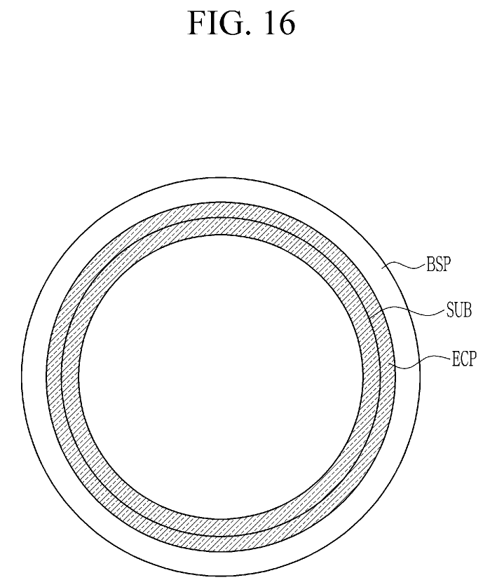

Referring to FIG. 16, the base portion BSP of the substrate supporting stage SCP according to an embodiment may have a substantially circular planar shape, and similar to this, the substrate SUB supported by the substrate supporting stage SCP may have a substantially circular planar shape.

The edge chucking portion ECP of the substrate supporting stage SCP may have a planar shape in the form of a circular ring located along the circumference of the substrate SUB.

The edge chucking portion ECP of the substrate supporting stage SCP may support the edges of the substrate SUB.

Many characteristics of the above-described embodiments may be applicable to the edge chucking portion according to the present embodiment.

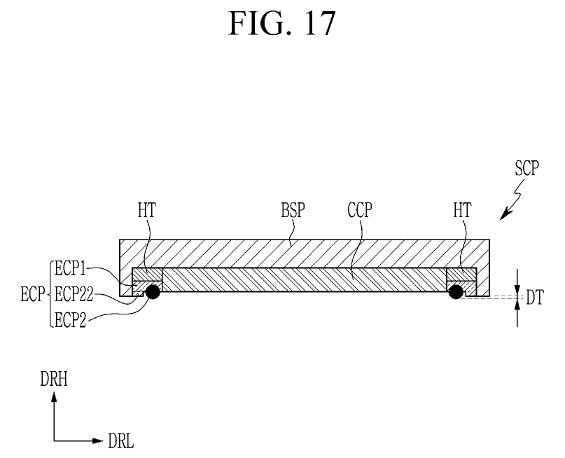

The substrate supporting stage SCP according to an embodiment will now be described with reference to FIG. 17. FIG. 17 shows a cross-sectional view of a substrate supporting stage according to an embodiment.

Referring to FIG. 17, the substrate supporting stage SCP according to the present embodiment may include a base portion BSP, a center chucking portion CCP, an edge chucking portion ECP, and a heater HT.

The edge chucking portion ECP of the substrate supporting stage SCP may include a main portion ECP1 and a second protruding portion ECP22 extending downward from the main portion ECP1 and may include an inserted portion ECP2 instead of the first protruding portion ECP21.

The inserted portion ECP2 may have a ball shape, and may include one of metal, ceramic, and polymer.

The inserted portion ECP2 of the edge chucking portion ECP may have a smaller cross-sectional area in accordance with a distance from the main portion ECP1 of the edge chucking portion ECP.

The thickness of the portion protruding from the main portion ECP1 from among the inserted portion ECP2 of the edge chucking portion ECP may be greater than the thickness of the second protruding portion ECP22 of the edge chucking portion ECP, and the inserted portion ECP2 of the edge chucking portion ECP may protrude further than the second protruding portion ECP22 of the edge chucking portion ECP by the thickness difference DT.

When heat energy is supplied to the inserted portion ECP2 and the second protruding portion ECP22 of the edge chucking portion ECP from the heater HT, and pressure is applied from the outside, the second protruding portion ECP22 of the edge chucking portion ECP is transformed, and the inserted portion ECP2 may move toward the main portion ECP1. In this way, the substrate SUB may be sandwiched and held between the edge chucking portions ECP.

When the shape of the edge chucking portion ECP is restored, the inserted portion ECP2 is restored to the original position so that the inserted portion ECP2 may push the substrate SUB downward, the substrate SUB may be spaced away from the center chucking portion CCP, and the substrate SUB may be detached from the substrate supporting stage SCP. When the shape of the edge chucking portion ECP is restored to push the substrate SUB, the center chucking portion CCP may also release the substrate SUB.

According to the embodiment, the substrate SUB may be sandwiched and held between the edge chucking portions ECP, and the substrate SUB may be closely attached to the center chucking portion CCP that is an electrostatic chuck or an adhesive chuck and may be supported by the center chucking portion CCP. Hence, the substrate SUB may be supported by the center chucking portion CCP, and the edge portion of the substrate SUB may be additionally supported and affixed by the edge chucking portion ECP so that the substrate supporting stage SCP may stably support the substrate SUB.

When mounted on the substrate supporting stage SCP, the surface of the substrate SUB may protrude further than the base portion BSP of the substrate supporting stage SCP so that the surface of the substrate SUB may be closely attached to the mask MSK of the mask assembly MSKA to avoid unnecessary gaps. Therefore, generation of the shadow effect may be reduced during the deposition process, and the accuracy of the deposition process may be increased.

Many characteristics of the substrate supporting stage for deposition and the deposition device including the same according to the embodiment described with reference to FIGS. 1 to 16 may be applicable to the substrate supporting stage according to the present embodiment.

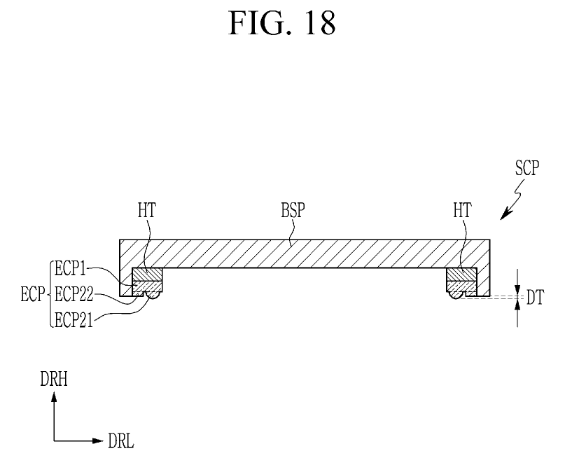

A substrate supporting stage SCP according to an embodiment will now be described with reference to FIG. 18. FIG. 18 shows a cross-sectional view of a substrate supporting stage according to an embodiment.

Referring to FIG. 18, the substrate supporting stage SCP according to the present embodiment is similar to the substrate supporting stage SCP according to the above-described embodiments. Descriptions of the same components will be omitted.

The substrate supporting stage SCP according to the present embodiment may not include the center chucking portion CCP, and may include the edge chucking portion ECP.

Many characteristics of the edge chucking portions ECP according to the above-described embodiments may be applicable to the edge chucking portion ECP of the substrate supporting stage SCP according to the present embodiment.

The first protruding portion ECP21 of the edge chucking portion ECP may have a smaller cross-section in accordance with a distance from the main portion ECP1 of the edge chucking portion ECP.

The thickness of the first protruding portion ECP21 of the edge chucking portion ECP may be greater than the thickness of the second protruding portion ECP22 of the edge chucking portion ECP, and the first protruding portion ECP21 may protrude further than the second protruding portion ECP22 by the thickness difference DT.

When heat energy is supplied by the heater HT to the first protruding portion ECP21 and the second protruding portion ECP22 of the edge chucking portion ECP, and pressure is applied from the outside, the first protruding portion ECP21 and the second protruding portion ECP22 of the edge chucking portion ECP may be transformed, and the substrate SUB may be sandwiched and held between the edge chucking portions ECP.

When the shape of the edge chucking portion ECP is restored, the first protruding portion ECP21 and the second protruding portion ECP22 are restored to the original shapes so that the first protruding portion ECP21 may push the substrate SUB downward, and the substrate SUB may be detached from the substrate supporting stage SCP.

Many characteristics of the substrate supporting stages for deposition and the deposition devices including the same according to the embodiments described with reference to FIGS. 1 to 17 may be applicable to the substrate supporting stage according to the present embodiment.

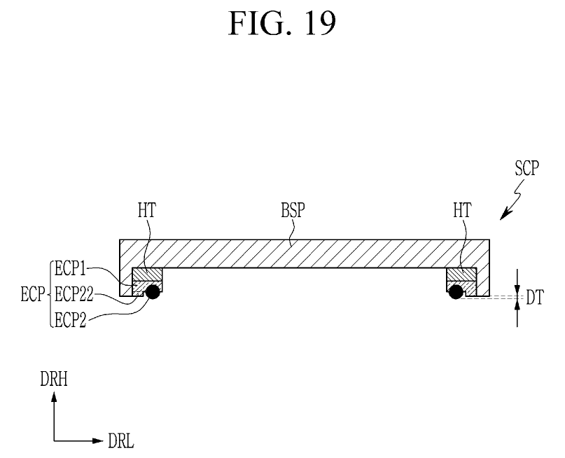

The substrate supporting stage SCP according to an embodiment will now be described with reference to FIG. 19. FIG. 19 shows a cross-sectional view of a substrate supporting stage according to an embodiment.

Referring to FIG. 19, the substrate supporting stage SCP according to the present embodiment is similar to the substrate supporting stage SCP according to the embodiment described with reference to FIG. 17. Descriptions of the same components will be omitted.

The substrate supporting stage SCP may not include the center chucking portion CCP and may include the edge chucking portion ECP.

Many characteristics of the edge chucking portions ECP according to the above-described embodiments may be applicable to the edge chucking portion ECP of the substrate supporting stage SCP according to the present embodiment.

The edge chucking portion ECP of the substrate supporting stage SCP may include a main portion ECP1 and a second protruding portion ECP22 extending downward from the main portion ECP1 and may include an inserted portion ECP2 instead of the first protruding portion ECP21.

The inserted portion ECP2 may have a ball shape, and may include one of metal, ceramic, and polymer.

The inserted portion ECP2 of the edge chucking portion ECP may have a smaller cross-section in accordance with a distance from the main portion ECP1 of the edge chucking portion ECP.

The thickness of the portion protruding from the main portion ECP1 from among the inserted portion ECP2 of the edge chucking portion ECP may be greater than the thickness of the second protruding portion ECP22 of the edge chucking portion ECP, and the inserted portion ECP2 of the edge chucking portion ECP may protrude further than the second protruding portion ECP22 of the edge chucking portion ECP by the thickness difference DT.

When the heater HT supplies heat energy to the inserted portion ECP2 and the second protruding portion ECP22 of the edge chucking portion ECP, and pressure is applied from the outside, the second protruding portion ECP22 of the edge chucking portion ECP is transformed, and the inserted portion ECP2 may move toward the main portion ECP1. In this way, the substrate SUB may be sandwiched and held between the edge chucking portions ECP.

When the shape of the edge chucking portion ECP is restored, the inserted portion ECP2 is restored to the original position so that the inserted portion ECP2 may push the substrate SUB downward, and the substrate SUB may be detached from the substrate supporting stage SCP.

Many characteristics of the substrate supporting stages for deposition and the deposition devices including the same according to the embodiments described with reference to FIGS. 1 to 18 may be applicable to the substrate supporting stage according to the present embodiment.

While this disclosure has been described in connection with what is presently considered to be practical embodiments, it is to be understood that the inventive concept is not limited to the disclosed embodiments, but, on the contrary, is intended to cover various modifications and equivalent arrangements included within the spirit and scope of the appended claims.

### DESCRIPTION OF SYMBOLS

100: deposition device

CHB: chamber

EP: deposition member

EM: deposition material

NZ: nozzle

MSKA: mask assembly

MSK: mask

MFR: mask frame

MBP: mask support bar

SUB: substrate

SCP: substrate supporting stage

BSP: base portion

BSP1: planar portion

BPS2: side wall portion

CCP: center chucking portion

ECP: edge chucking portion

ECP1: main portion

ECP21, ECP22: protruding portion

ECP2: inserted portion

What is claimed is:

1. A substrate supporting stage for deposition comprising:
a base portion;
an edge chucking portion located on a lateral surface of a side wall of the base portion; and
a heater located on the edge chucking portion,
wherein the edge chucking portion includes a main portion, a first protruding portion, and a second protruding portion, the first protruding portion and the second protruding portion extending downward from the main portion in a height direction, and
the first protruding portion has a cross-section narrowed in accordance with a distance from the main portion in the height direction.

2. The substrate supporting stage of claim 1, wherein,
the second protruding portion is located between the side wall and the first protruding portion in a planar direction that is perpendicular to the height direction, and
a cross-section of the second protruding portion is substantially constant in the height direction.

3. The substrate supporting stage of claim 2, wherein,
a first thickness of the first protruding portion is not equal to a second thickness of the second protruding portion.

4. The substrate supporting stage of claim 3, wherein,
the first thickness is greater than the second thickness.

5. The substrate supporting stage of claim 4, wherein,
the second protruding portion does not protrude downward further than the side wall in the height direction.

6. The substrate supporting stage of claim 5, wherein,
the first protruding portion protrudes downward further than the side wall in the height direction.

7. The substrate supporting stage of claim 1, wherein,
the edge chucking portion includes a shape memory material.

8. The substrate supporting stage of claim 7, wherein,
the main portion, the first protruding portion, and the second protruding portion include the shape memory material.

9. The substrate supporting stage of claim 8, further comprising:
a center chucking portion located below the base portion in the height direction and located on a lateral surface of the edge chucking portion in a planar direction that is perpendicular to the height direction.

10. The substrate supporting stage of claim 7, wherein,
the main portion and the second protruding portion include the shape memory material, and
the first protruding portion includes a ball inserted into the main portion.

11. The substrate supporting stage of claim 10, further comprising:
a center chucking portion located below the base portion in the height direction and located on a lateral surface of the edge chucking portion in a planar direction that is perpendicular to the height direction.

12. A deposition device comprising:
a chamber for providing a process region;
a deposition member located in the chamber and providing a process material;
a substrate supporting stage opposite the deposition member in a height direction and supporting a substrate; and
a mask assembly located between the substrate supporting stage and the deposition member,
wherein the substrate supporting stage includes:
a base portion;
an edge chucking portion located on a lateral surface of a side wall of the base portion, and
a heater located on the edge chucking portion,
the edge chucking portion includes a main portion, a first protruding portion, and a second protruding portion, the first protruding portion and the second protruding portion extending downward from the main portion in a height direction, and
the first protruding portion has a cross-section narrowed in accordance with a distance from the main portion in the height direction.

13. The deposition device of claim 12, wherein,
the second protruding portion is located between the side wall and the first protruding portion in a planar direction that is perpendicular to the height direction, and
a cross-section of the second protruding portion is substantially constant in the height direction.

14. The deposition device of claim 13, wherein,
a first thickness of the first protruding portion is greater than a second thickness of the second protruding portion.

15. The deposition device of claim 14, wherein,
the first protruding portion protrudes downward further than the side wall in the height direction, and
the second protruding portion does not protrude downward further than the side wall in the height direction.

16. The deposition device of claim 12, wherein,
the edge chucking portion includes a shape memory material.

17. The deposition device of claim 16, wherein,
the main portion, the first protruding portion, and the second protruding portion include the shape memory material.

18. The deposition device of claim 17, further comprising:
a center chucking portion located below the base portion in the height direction and located on a lateral surface of the edge chucking portion in a planar direction that is perpendicular to the height direction.

19. The deposition device of claim 16, wherein,
the main portion and the second protruding portion include the shape memory material, and
the first protruding portion includes a ball inserted into the main portion.

20. The deposition device of claim 19, wherein,
a center chucking portion is located below the base portion in the height direction and located on a lateral surface of the edge chucking portion in a planar direction that is perpendicular to the height direction.
